(19) United States
(12) Patent Application Publication
(10) Pub. No.: US 2010/0096642 A1
(43) Pub. Date: Apr. 22, 2010

(54) PACKAGING STRUTURE FOR HIGH POWER LIGHT EMITTING DIODE(LED) CHIP

(75) Inventors: Chung-Chi Chang, Taipei City (TW); Hao-Jan Yu, Chungli City (TW)

Correspondence Address: BRILLIANT TECHNOLOGY CO., LTD., P.O.BOX 108-00403, Taipei, 106, omitted

(73) Assignee: BRILLIANT TECHNOLOGY CO., LTD., Tau-Yuan (TW)

(21) Appl. No.: 12/254,821

(22) Filed: Oct. 20, 2008

(51) Int. Cl. H01L 33/00

(52) U.S. Cl. 257/88; 257/99; 257/E33.058

(57) ABSTRACT

The present invention relates to a packaging structure for high-power light emitting diode (LED) chip, comprising a metal plate, insulators and a cover plate. The metal plate comprises a containing slot and isolating slots formed on the surface by working, and the insulators can be embedded in the isolating slot. After forming a hollow slot and notches on the surface of the cover plate by working, the cover plate is combined with the metal plate and insulators and at the same time, the hollow slot and the notches are corresponding to the containing slot and the isolating slots on the metal plate to form a hollowness state, followed by application of surface treatment to form soldering portions and an anti-soldering layer at the bottom of the metal plate. Then the metal plate is cut on both sides along free ends of the insulators so as to generate electrode contacts with positive and negative electrodes, and the surface mount technology (SMT) can be adopted for assembly of the packaging structure of high-power LED chip so as to simplify manufacturing processes, facilitate mass production and achieve separation of electricity from heat, etc.

### BACKGROUND OF THE INVENTION

1. Field of the Invention

The present invention relates to a packaging structure for high-power LED chip, especially to a packaging structure for high-power LED chip that can achieve such functions as simplifying manufacturing processes, facilitating mass production and isolating electricity from heat, etc., which is formed by embedding the insulators in the metal plate, combining the cover plate with the metal plate and the insulators and cutting the metal plate on both sides along the free ends of the insulators to form electrode contacts.

2. Description of Related Art

With regard to the structure of the chip on board (COB) for the conventional chips, take the packaging of LED chip as an example and refer to FIG. 10. A chip A is mounted in a flex arc B1 of an insulator B and a wire A1 connected and extended from the chip A is connected with a positive electrode pin C and a negative electrode pin D installed in the insulator B respectively. Then the packaging process is carried out outside the chip A, and such kind of low-power LED will be formed. However, there are also many problems and disadvantages.

1. There is no component installed in the insulator B for radiating heat produced from the chip A. Therefore, this may lead to disadvantages and problems of poor heat radiation or difficulty in heat dissipation when the chip A emits light, resulting in considerable increase of heat resistance, lower performance, or shortened service life of the chip A due to overheat.

2. The positive electrode pin C and the negative electrode pin D is electrically connected with a circuit board by insertion. This makes the overall height of the low-power LED unable to be reduced effectively; rather it will occupy some space. So it will not meet the requirement for thin products in design.

3. The light emitted from the chip A is liable to scattering, resulting in loss of light, this will lead to attenuation and loss in brightness of low-power LED and further impact illumination quality. Moreover, the effect will not be apparent.

Additionally refer to FIG. 11, a chip A is fixed in a heat radiating base B2 embedded in an insulator B, and a connecting wire A1 of the chip A is connected with a positive electrode pin C and a negative electrode pin D respectively on both sides of the insulator B. After packaging of a glue E and combination of a transmittance body F, a high-power LED is formed. However, there are also many disadvantages.

1. The heat radiating base B2 in the insulator B can only be used to accommodate a single chip A, so the overall brightness will be limited. However, if the overall brightness needs to be lifted, it will require several high-power LEDs to be installed simultaneously on a circuit board, and these LEDs will occupy certain space, quantities and costs.

2. The heat energy generated from the chip A will be accumulated on the circuit board through the heat radiating base B2, and it is difficult to be removed because of small heat radiating area of the heat radiating base B2, resulting in lower performance of the chip A or shortened service life of the chip A due to overheat.

Therefore, how to overcome the above defect is the target for the manufactures in the field.

### SUMMARY OF THE INVENTION

The primary objective of the present invention lies in forming at least one containing slot for mounting a chip on the surface of a metal plate, opening two isolating slots on two external sides of the containing slot in converse directions, and embedding insulators in the isolating slots. The metal plate and the insulators are covered and combined with a cover plate, allowing a hollow slot and notches on the surface of the cover plate to correspond with the containing slot and the isolating slots to form a hollowness state. Then, the metal plate is cut on both sides along the free ends of the insulators so as to form electrode contacts with positive and negative electrodes, and the surface mount technology (SMT) can be adopted for assembly to simplify manufacturing processes and facilitate mass production, hence, raise production and manufacturing efficiency.

The secondary objective of the present invention is that the electrode contacts of the metal plate are insulated from the containing slot through the insulators, so that the heat energy generated from the chip inside the containing slot can radiate quickly to the metal plate along the bottom of the chip. In this way, it can prevent heat energy from accumulating on the chip and prolong the service life of the chip by reducing its thermal resistance and luminance attenuation, and does not impact stability and reliability of electrical transmission for the electrode contacts, thus achieving the effect of separating electricity from heat.

### BRIEF DESCRIPTION OF THE DRAWING

FIG. 1 is an elevation view according to one preferred embodiment of the present invention.

FIG. 2 is an exploded view according to one preferred embodiment of the present invention.

FIG. 3 is a front elevation view according to one preferred embodiment of the present invention, before cutting.

FIG. 4 is an elevation view according to one preferred embodiment of the present invention, after cutting.

FIG. 5 is a sectional side view of FIG. 4.

FIG. 6 is a flow chart according to one preferred embodiment of the present invention.

FIG. 7 is a front view according to one preferred embodiment of the present invention.

FIG. 8 is a sectional side view according to one preferred embodiment of the present invention.

FIG. 9 is a front view according to another preferred embodiment of the present invention.

FIG. 10 is an elevation view of a conventional low-power LED.

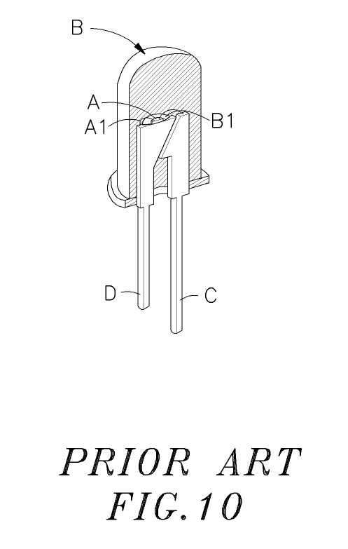

FIG. 11 is an elevation view of a conventional high-power LED.

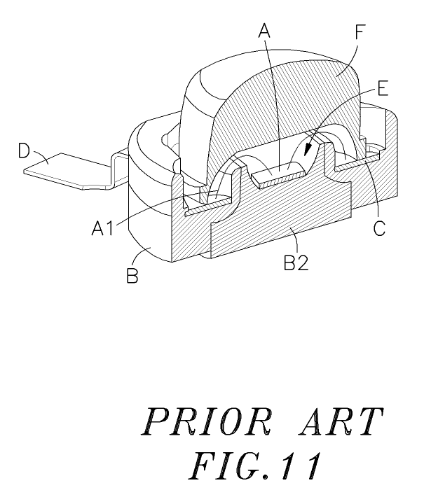

### DETAIL DESCRIPTION OF THE INVENTION

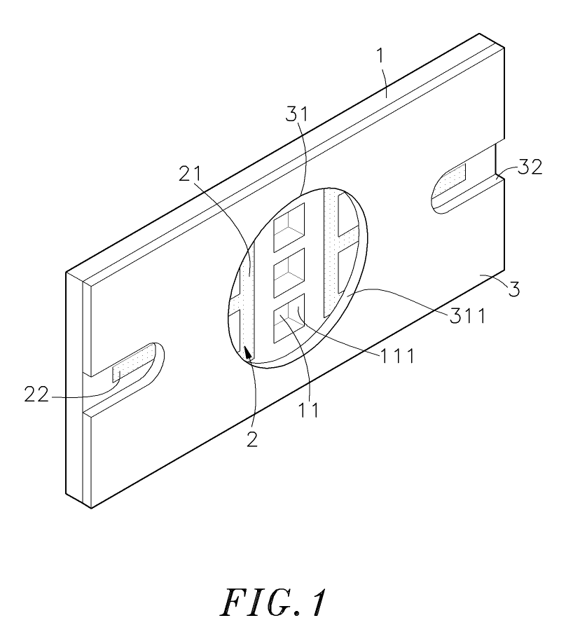

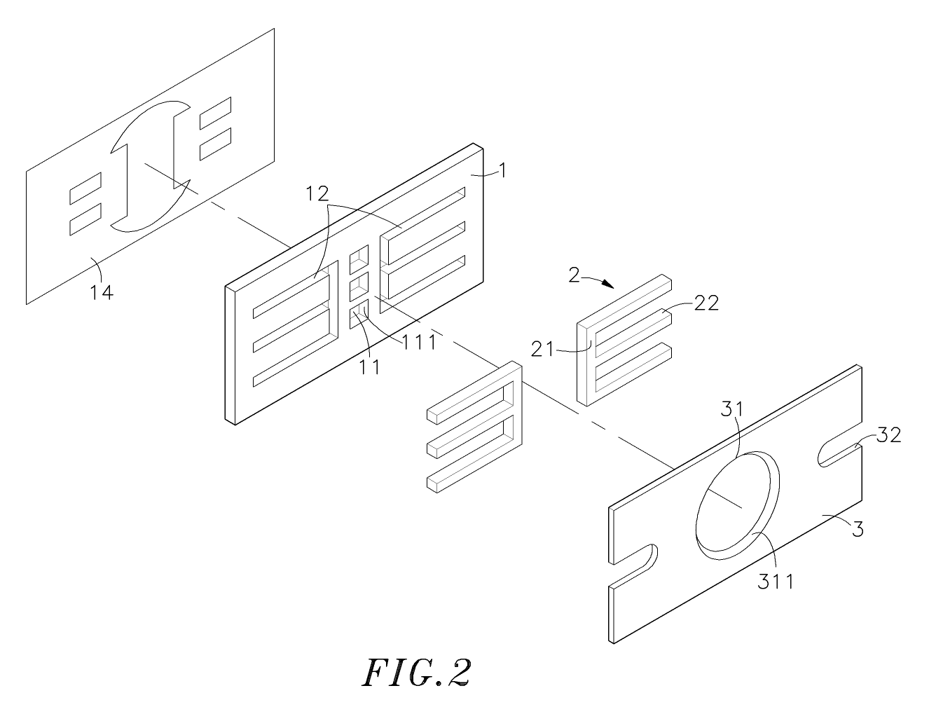

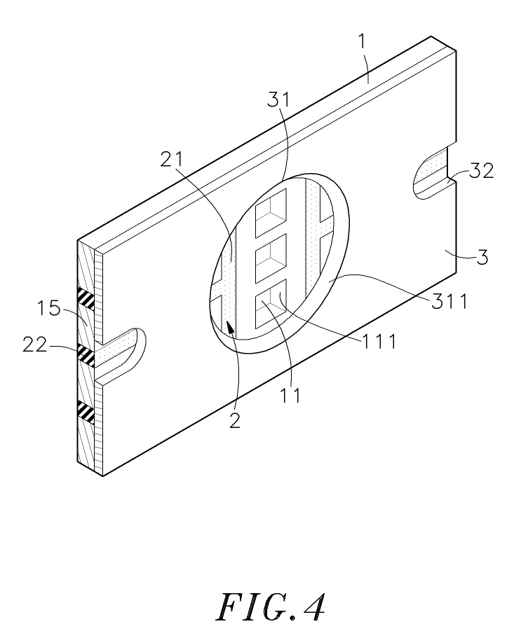

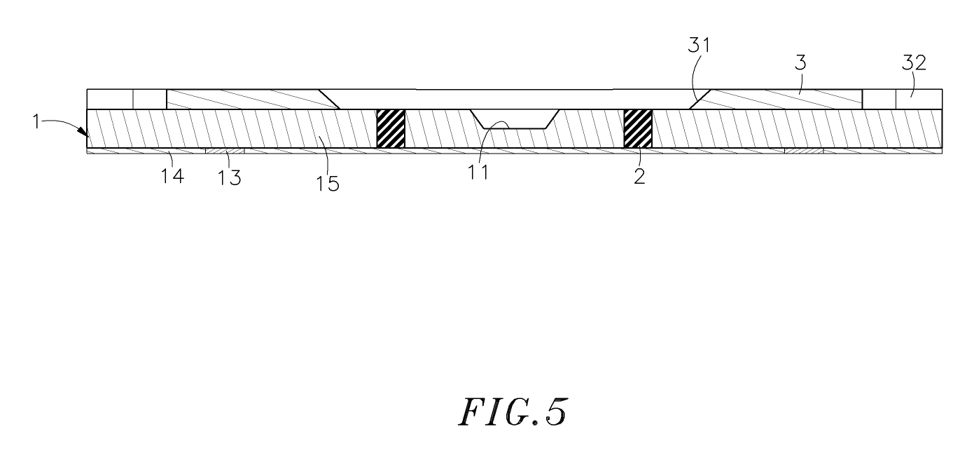

Referring to FIGS. 1, 2, 3, 4 and 5, a packaging structure of the present invention is shown comprised of a metal plate 1, complex insulators 2 and a cover plate 3.

The metal plate 1 comprises at least one containing slot 11 in the form of concave cone at the center surface, two isolating slots 12 established in opposite directions on the outer sides of the containing slot 11, two soldering portions 13 at the bottom side between the containing slot 11 and the isolating slots 12, and an anti-soldering layer 14 formed on the external edge of the soldering portions 13. In addition, the containing slot 11 has a light-conducting surface 111 at vertical or inclination angle on inner wall thereof.

The insulators 2 are set in the size that fits with the isolating slots 12. Each of the insulators 2 comprises a base 21, and extended portions 22 arranged at an interval extended from one side of the base 21.

The cover plate 3 comprises a circular hollow slot 31 at the center surface, and a light-conducting surface 311 at vertical or inclination angle is formed on inner side of the circular hollow slot 31. Moreover, two rectangular notches 32 are formed on both sides of the cover plate 3 in the direction towards the hollow slot 31.

To complete assembly for the present invention, firstly, the insulators 2 are mounted into the two isolating slots 12 of the metal plate 1, then, the cover plate 3 is combined and integrated with the metal plate 1 and the insulators 2. At the same time, the hollow slot 31 and the notches 32 of the cover plate 3 are corresponding to the containing slot 11 and the isolating slots 12 on the metal plate 1 to form the hollowness state, so that the extended portions 22 of the insulators 2 can project from the hollow slot 31 and the notches 32 of the cover plate 3, and then the overall assembly for the present invention will be completed.

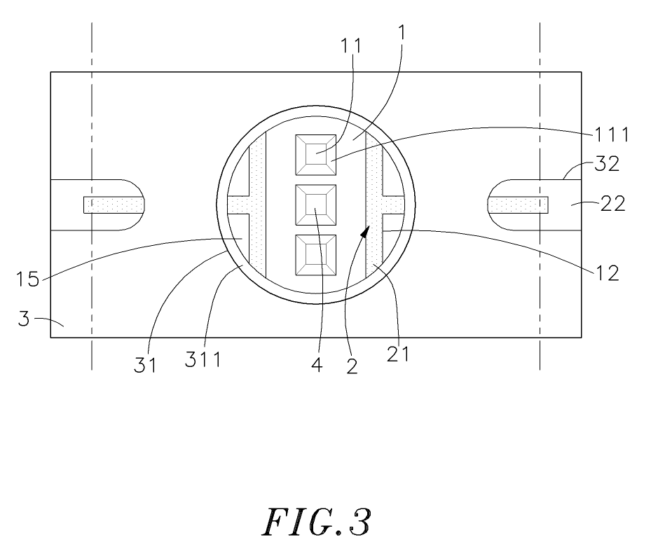

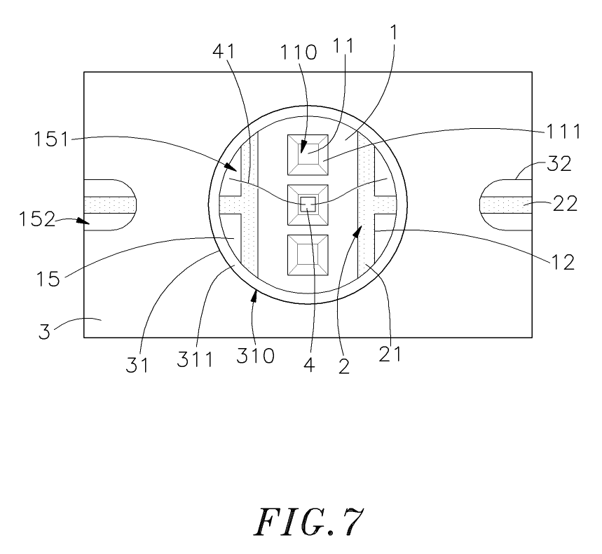

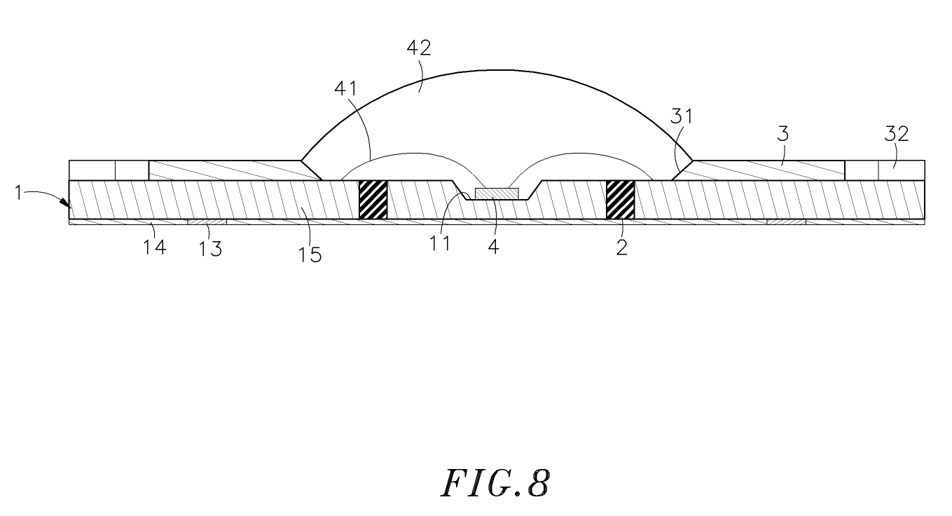

At time of use, the metal plate 1 that has been combined with the insulator 2 and the cover plate 3 as indicated above can be cut longitudinally (or transversely) on both sides along the line close to the free end of the extended portions 22 of the insulators 2 (as shown in FIGS. 3, 4 and 5). After the metal plate 1 has been cut, the parts between the extended portions 22 are isolated to form electrode contacts 15, which have positive or negative electrodes. In addition, because the electrode contacts 15 are isolated from the containing slot 11 of the metal plate 1 via the insulators 2, therefore, the heat energy generated from at least one chip 4 mounted in the containing slot 11 of the metal plate 1 (as shown in FIGS. 7 and 8) can be quickly dispersed along the bottom of the chip 4 to the metal plate 1, thus preventing the heat energy from accumulating on the chip 4 and prolonging the service life of the chip 4 by reducing the thermal resistance and luminance attenuations. Besides, it also will not impact stability and reliability of the electric transmission of the electrode contacts 15, hence separation of electricity from heat is achieved.

Moreover, two wires 41 connected to the chip 4 mounted in the containing slot 11 of the metal plate 1 (as shown in FIG. 8) can be linked electrically with positive and negative electrodes of the electrode contacts 15 respectively, thus forming the packaging structure for high-power LED chip with the chip on board (COB) technology.

In addition, because the soldering portions 13 are formed between the containing slot 11 and the isolating slots 12 by using the surface treatment, therefore, the high-power LED chip of the present invention can be a surface mounted device (SMD) that is fixed on a circuit substrate by using the surface mount technology (SMT). It can not only reduce the height required in overall structural design effectively, but also achieve the effects of structural simplicity and stability as well as satisfying design requirements for thin products.

Furthermore, the light-conducting surfaces 111 and 311 at vertical or inclination angles are formed on the inner walls of the containing slot 11 of the metal plate 1 and the hollow slot 31 of the cover plate 3 respectively to offer the excellent reflecting angles for the packaged chip 4 at time of light emitting, so that the light emitted by the chip 4 can be condensed before being projected, reducing luminance attenuation and loss. In this way, the brightness of the high-power LED can be enhanced. Moreover, the light-conducting surface 111 inside the containing slot 11 of the metal plate 1 can also be used as a blocking edge for the fluorescent powders to reduce consumption of the fluorescent powders. In addition, the light-conducting surface 311 inside the hollow slot 31 of the cover plate 3 can also prevent a molding gel 42 (as shown in FIGS. 7 and 8) from overflowing in the packaging process, and also allows the molding gel 42 to present a complete shape after hardening, so as to project the light emitted from the chip 4 evenly and generate better illumination results and quality.

The isolating slot 12 of the metal plate 1 as stated above may be shaped like E, M and U, or installed in interval arrangements or in the form of lattices, and the metal plate 1 can be made of metal materials with good electric and thermal conductivity, such as copper or aluminum; the insulator 2 can be made of ceramic, high polymer or compound material; the cover plate 3 can be made of metal materials, ceramic, high polymer or compound material. Besides, the metal plate 1 and the cover plate 3 can form a rectangular, circular, square, elliptic or polygonal shape. Furthermore, the hollow slot 31 and the notch 32 of the cover plate 3 can form a rectangular, circular, elliptic or polygonal shape (not shown in the figure), as long as the extended portions 22 of the insulators 2 project over the hollow slot 31 and the notches 32 of the cover plate 3.

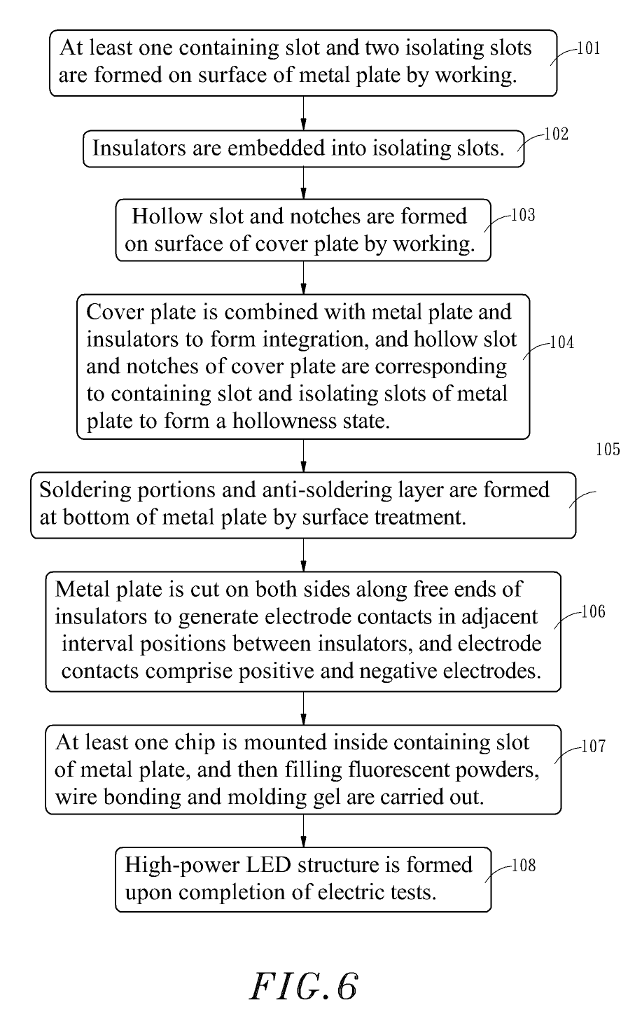

Referring to FIGS. 6, 7 and 8, when the manufacturing method of the present invention is used for processing, the steps are described as following.

(101) At least one containing slot 11 and two isolating slots 12 are formed on the surface of the metal plate 1 by working.

(102) The insulators 2 are embedded into the isolating slots 12.

(103) A hollow slot 31 and notches 32 are formed on the surface of the cover plate 3 by working.

(104) The cover plate 3 is combined with the metal plate 1 and the insulators 2 to form integration, and the hollow slot 31 and the notches 32 of the cover plate 3 are corresponding to the containing slot 11 and the isolating slots 12 of the metal plate 1 to form a hollowness state.

(105) Soldering portions 13 and an anti-soldering layer 14 are formed at the bottom of the metal plate 1 by the surface treatment.

(106) The metal plate 1 is cut on the both sides along the free ends of the insulators 2 to generate electrode contacts 15 in the adjacent interval positions between the insulators 2, and the electrode contacts 15 comprise positive and negative electrodes.

(107) At least one chip 4 is mounted inside the containing slot 11 of the metal plate 1, and then filling of the fluorescent powders, wire bonding and molding gel are carried out.

(108) A high-power LED structure is formed upon completion of electric tests.

On the other hand, the following steps can also be taken to complete processing:

(201) At least one containing slot 11 and isolating slots 12 are formed on the surface of the metal plate 1 by working.

(202) The insulators 2 are embedded into the isolating slots 12.

(203) Soldering portions 13 and an anti-soldering layer 14 are formed at the bottom of the metal plate 1 with the surface treatment.

(204) A hollow slot 31 and notches 32 are formed on the surface of the cover plate 3 through working.

(205) The cover plate 3 is combined with the metal plate 1 and the insulators 2 to form integration, and the hollow slot 31 and the notches 32 of the cover plate 3 are corresponding to the containing slot 11 and the isolating slots 12 of the metal plate 1 to form a hollowness state.

(206) The metal plate 1 is cut on the both sides along the free ends of the insulators 2 to generate electrode contacts 15 in the adjacent interval positions between the insulators 2, and the electrode contacts 15 comprise positive and negative electrodes.

(207) At least one chip 4 is mounted inside the containing slot 11 of the metal plate 1, and then filling of the fluorescent powders, wire bonding and molding gel are carried out.

(208) A high-power LED structure is formed upon completion of electric tests.

The working for forming the containing slot 11 and the isolating slot 12 on the surface of the metal plate 1 as described above may include such means of machining, chemical etching or punching, etc, wherein the containing slot 11 has a die bonding area 110, in which there is at least one proposed chip 4 located and which can be filled with the fluorescent powders. Furthermore, the isolating slots 12 can be used for embedding and fixing the insulators 2 generated with silk screening, roller coating, and integrated injection molding, etc. In addition, the working for forming the hollow slot 31 and the notches 32 on the surface of the cover plate 3 may include such means of machining, chemical etching or integrated injection molding, etc. Then, the cover plate 3 is combined with the metal plate 1 and the insulators 2 to form integration, and the hollow slot 31 and the notches 32 of the cover plate 3 are corresponding to the containing slot 11 and the isolating slots 12 of the metal plate 1 to form a hollowness state.

Besides, the surface treatment can be utilized to form the soldering portions 13 at the bottom of the metal plate 1 between the containing slot 11 and the isolating slots 12, and the soldering portions 13 will allow the packaging structure of the present invention be fixed on a circuit substrate by using surface mount technology (SMT), while the surface treatment may include electroplating and sputtering, etc. Then, the surface treatment is used to form the anti-soldering layer 14 on the exterior edge of the soldering portions 13, and the surface treatment includes silk screening, roller coating or spraying. After that, the metal plate 1 can be cut on both sides along the free ends of the extended portions 22 of the insulators 2 to form the electrode contacts 15 in the adjacent interval positions between the insulators 2 and the electrode contacts 15 have positive and negative electrodes. At the same time, a wire bonding area 151 and an electric testing area 152 are formed respectively nearby the interior edges of the electrode contacts 15 that project over the hollow slot 31 and the notches 32 of the cover plate 3.

Afterwards, the conducting wire 41 connected to the proposed chip 4 can be electrically connected with positive and negative electrodes of the electrode contacts 15 in the wire bonding area 151 on the metal plate 1. After forming a molding gel area 310 on the hollow slot 31 of the cover plate 3 corresponding to the containing slot 11 of the metal plate 1, the molding gel 42 is carried out on the molding gel area 310 and the surface of the chip 4, and the structure of high-power LEDs will be formed upon completion of electric tests, so as to achieve the purposes of simplifying manufacturing processes, facilitating mass production and raising production and processing efficiency and to gain advantages in easy quality control and effective reduction in costs.

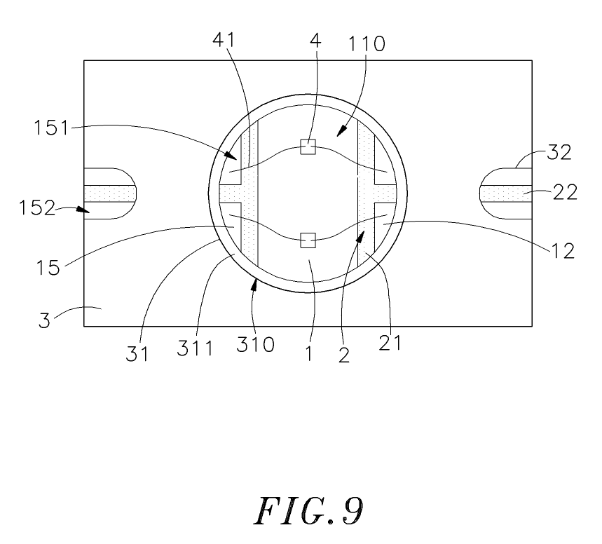

According to the step (103) to step (105) as described above, the hollow slot 31 and the notches 32 are formed by means of working on the surface of the cover plate 3, the cover plate 3 is combined with the metal plate 1 and the insulators 2 to from integration, and then the surface treatment is applied to form the soldering portions 13 and the anti-soldering layer 14 at the bottom of the metal plate 1. While being applied, however, the manufacturing method in the present invention shall not be limited to the sequence of the steps as indicated above. And proper changes in the sequence of the step (101)˜(104) may be made, provided that this will not have effect on the overall features of the present invention that are to be protected. For example, the method may start with forming the soldering portions 13 and the anti-soldering layer 14 on the surface of the metal plate 1 by means of the surface treatment, followed by use of working means to form the hollow slot 31 and the notches 32 on the surface of the cover plate 3, and then the cover plate 3 is combined with the metal plate 1 and the insulators 2 to from integration. In addition, the example of one preferred embodiment given above is based on the descriptions that there is at least one containing slot 11 with the die bonding area 110 on the surface of the metal plate 1, and at least one chip 4 is mounted inside the die bonding area 110. However, the die bonding area 110 may also be formed directly on the surface of the metal plate 1 (as shown in FIG. 9) without the containing slot 11, i.e. the die bonding area 110 may be mounted with at least one chip 4.

Therefore, the packaging structure for high-power LED chip of the present invention has the advantages as follows:

1. In the present invention, the isolating slots 2 of the metal plate 1 are embedded with the insulators 2, and after combining the cover plate 3 with the metal plate 1 and the insulators 2, the metal plate 1 is cut on both sides along the free ends of the insulators 2 to separate out the electrode contacts 15, and the surface mount technology (SMT) can be used for assembly to form the packaging structure for high-power LED chip, so as to achieve the purposes of simplifying manufacturing processes, facilitating mass production, thus raising production and processing efficiency.

2. The electrode contacts 15 of the metal plate 1 in the present invention are insulated from the containing slot 11 of the metal plate 1 through the insulators 2, which allows the heat energy generated from the chip 4 in the containing slot 11 to be dispersed to the metal plate 1 along the bottom of the chip 4, thus preventing heat energy from accumulating on the chip 4 and prolonging the service life of the chip 4 by reducing the thermal resistance and luminance attenuation relatively, without impacting stability and reliability of electric transmission of the electrode contacts 15. In such way, the effect of separation of electricity from heat will be achieved.

3. On the surface of the metal plate 1 of the present invention, there is at least one containing slot 11, in which at least one chip 4 is fixed. Then, the wire 41 connected to the chip 4 can be connected electrically with the positive and negative electrodes of the electrode contacts 15 on the metal plate 1 respectively, and sharing one body can result in less space, number of components and cost than what is required for installing components independently on the circuit board.

4. The soldering portions 13 are formed at the bottom of the metal plate 1 between the containing slot 11 and the isolating slots 12. By means of surface treatment, the soldering portions 13 allow the packaging structure of the present invention to be fixed on the circuit substrate through the surface mount technology (SMT). This can not only reduce the overall height, but also achieve simple and stable structure, in addition to meeting the design requirement for thin products.

5. In the present invention, the light-conducting surface 111 inside the containing slot 11 of the metal plate 1 can be used as the blocking edge for the fluorescent powders to reduce consumption of fluorescent, and can provide excellent reflection angles for light from the chip 4, which allows the light emitted from the chip 4 to be condensed before being projected, thus reducing the possibilities of luminance attenuation and loss and enhancing brightness of high-power LEDs.

6. In the present invention, the light-conducting surface 311 inside the hollow slot 31 of the cover plate 3 can prevent the molding gel 42 from overflowing in the packaging process, and allows the molding gel 42 to present a complete shape after hardening, so as to project the bright from the chip 4 evenly and generate better illumination results and quality.

While the invention has been described in conjunction with a specific best mode, it is to be understood that many alternatives, modification, and variations will be apparent to those skilled in the art in light of the foregoing description. Accordingly, it is intended to embrace all such alternatives, modification, and variations in which fall within the spirit and scope of the included claims. All matters set forth herein or shown in the accompanying drawings are to be interpreted in an illustration and non-limiting sense.

What the invention claimed is:

1. A packaging structure for high-power light emitting dioxide (LED) chip, comprising:
a metal plate, said metal plate having a die bonding area formed on a surface for mounting at least one chip, and two isolating slots set up in reverse directions on two external opposite sides of said die bonding area;
two insulators, said insulators made in the size that fits with said isolating slots and can be embedded into said insolating slots, and each comprising a base, and a plurality of extended portions in interval arrangements extended from one side of said base; and
a cover plate, said cover plate combined with said metal plate and said insulators, and comprising a hollow slot on its surface, and two notches formed on two side edges;
wherein, after combining, said hollow slot and said notches of said cover plate are corresponding to said containing slot and said isolating slots of said metal plate respectively to form a hollowness state, and then the metal plate is cut on both sides along free ends of said extended portions of said insulators to form electrode contacts between said adjacent insulators.

2. The packaging structure for high-power LED chips according to claim 1, wherein said metal plate further comprises at least one containing slot on the surface, and said die bonding area is in said containing slot for mounting said chip.

3. The packaging structure for high-power LED chips according to claim 2, wherein light-conducting surfaces at vertical or inclination angles are formed on inner sidewalls of said containing slot of said metal plate.

4. The packaging structure for high-power LED chips according to claim 2, wherein said containing slot formed on the surface of said metal plate is by means of working, and the working methods may include means of machining, chemical etching and punching.

5. The packaging structure for high-power LED chips according to claim 1, wherein said isolating slots formed on the surface of said metal plate is by means of working, and the working methods may include such means of machining, chemical etching and punching.

6. The packaging structure for high-power LED chips according to claim 1, wherein said isolating slots can be shaped like E, M, and U, or installed in interval arrangements or in the form of lattices.

7. The packaging structure for high-power LED chips according to claim 1, wherein said electrode contacts have both positive electrodes and negative electrodes, and wires connected to said chip can be connected electrically with said positive electrodes and said negative electrodes respectively.

8. The packaging structure for high-power LED chips according to claim 1, wherein said metal plate comprises soldering portions at the bottom between said die bonding area and said isolating slots by a surface treatment which may be electroplating or sputtering.

9. The packaging structure for high-power LED chips according to claim 8, wherein an anti-soldering layer is formed on the external edges of said soldering portions at the bottom of said metal plate by a surface treatment which may be silk screening, roller coating and spraying, etc.

10. The packaging structure for high-power LED chips according to claim 1, wherein said metal plate may be made of metal materials with electric and thermal conductivity, such as copper and aluminum.

11. The packaging structure for high-power LED chips according to claim 1, wherein said insulators may be made of ceramic, high polymer and compound materials.

12. The packaging structure for high-power LED chips according to claim 1, wherein said insulators may be made through the processing method of silk screening, roller coating and integrated injection molding, etc.

13. The packaging structure for high-power LED chips according to claim 1, wherein light-conducting surfaces at vertical or inclination angles are formed on the internal sidewalls of said hollow slots on said cover plate.

14. The packaging structure for high-power LED chips according to claim 1, wherein said hollow slot and said notches formed on the surface of said cover plate is by means of working, and the working methods may include such means of machining, chemical etching and integrated injection molding, etc.

15. The packaging structure for high-power LED chips according to claim 1, wherein said cover plate may be made of metal, ceramic, high polymer and composite materials.

16. The packaging structure for high-power LED chips according to claim 1, wherein a wire bonding area and an electric testing area are formed on said metal plate where said electrode contacts project over said hollow slots and said notches of said cover plate.

17. The packaging structure for high-power LED chips according to claim 1, wherein said metal plate and said cover plate may be of a rectangular, circular, elliptic and polygonal shape.

18. The packaging structure for high-power LED chips according to claim 1, wherein said hollow slot and said notches of said cover plate may be of a rectangular, circular, elliptic and polygonal shape.
